(19) United States
(12) Patent Application Publication
(10) Pub. No.: US 2006/0091550 A1
(43) Pub. Date: May 4, 2006

(54) Method of analyzing operation of semiconductor integrated circuit device, analyzing apparatus used in the same, and optimization designing method using the same

(75) Inventors: Kenji Shimazaki, Kobe-shi (JP); Kazuhiro Satoh, Neyagawa-shi (JP); Hiroyuki Tsujikawa, Kusatsu-shi (JP); Shouzou Hirano, Osaka-shi (JP); Makoto Nagata, Kobe-shi (JP)

Correspondence Address: PANASONIC PATENT CENTER;c/o MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD.

(21) Appl. No.: 11/231,810

(22) Filed: Sep. 22, 2005

(30) Foreign Application Priority Data
Sep. 30, 2004 (JP) P2004-287544

(51) Int. Cl. H01L 23/52

(52) U.S. Cl. 257/758

(57) ABSTRACT

In a method of analyzing a power noise based on the circuit information of a semiconductor integrated circuit device, the power noise is analyzed in consideration of the influence of the impedance of a substrate. Consequently, the impedance of the substrate which has not been conventionally considered is taken into consideration. Thus, precision in the analysis can be enhanced more greatly.

This application is based on Japanese Patent Application No. 2004-287544, which is incorporated herein by reference.

### BACKGROUND OF THE INVENTION

1. Field of the Invention

The present invention relates to a method of analyzing the operation of a semiconductor integrated circuit device, an analyzing apparatus to be used in the method, and an optimization designing method using the apparatus, and more particularly to a method of analyzing an operation at a high speed with high precision for a large scale and high-speed driving LSI (a large scale semiconductor integrated circuit).

2. Description of the Related Art

In a design for a semiconductor integrated circuit, usually, it is important that a timing is analyzed as to whether a timing between flip-flops is matched, thereby carrying out an optimization. For this reason, there has been employed a method of analyzing the operation of a circuit, calculating a delay value and carrying out an optimum design in such a manner that the delay value is set within an allowable range. With an increase in the speed and integration of the semiconductor integrated circuit, however, the numbers of circuit units such as transistors, resistors and capacities constituting the semiconductor integrated circuit have been increased steadily. Therefore, it is necessary to analyze an operation with very high precision.

For this reason, the calculation of the delay value with high precision has been an important requirement. Consequently, various methods have been proposed.

Conventionally, a logical simulation for analyzing the operation of a circuit is carried out in consideration of a variation in a source voltage, a change in an operating temperature and a fluctuation in a process in addition to a typical delay condition.

However, it is impossible to disregard the influence of a slight simulation error on the delay of each element due to an enhancement in the degree of an integration.

Therefore, there has been proposed a delay calculating method of calculating a fluctuation in a voltage by a power wiring and a ground wiring to enhance a reliability in consideration of a fluctuation in a voltage for each type of an element (see JP-A-2000-195960 (paragraph [0015] and [0017] and FIG. 1)).

In this method, the source voltage of each element is calculated in consideration of a fluctuation in a voltage in the power wiring and the ground wiring of a designing object circuit and a delay value is calculated for each element by using the source voltage of each element which is thus calculated.

In this method, a fluctuation in a voltage is calculated based on information about an element voltage fluctuation resistance value read from a library storing the voltage fluctuation resistance value for each element and an average source current value in an operation for each type of the element. Accordingly, information about the fluctuation in a voltage for each type of an element thus obtained is information about an average voltage for each type of the element in the circuit. Although the amount of a calculation is large, the same information is insufficient for carrying out an analysis with high precision. On the other hand, the inventors have proposed a method of carrying out a timing analysis by using the electric potential fluctuation waveforms of a power supply and a ground through a method of analyzing a power noise with high precision.

Examples of the method of analyzing a power noise with high precision which obtains the electric potential fluctuation waveforms of a power supply and a ground include a method of carrying out an analysis using a transistor level simulator which is generally referred to as “SPICE (Software Process Improvement and Capability Determination). The method serves to carry out a transient analysis for a current and a voltage in a network adding a power wiring resistor Rvdd and ground wiring resistor Rvss to a transistor network, thereby calculating an electric potential fluctuation waveform on a node of each element and a power wiring and ground wiring as shown in FIG. 1.

Moreover, there has also been proposed a method of analyzing a power noise on a gate level in order to decrease the amount of a calculation in the analysis. In this method, for example, transistors Tr1 and Tr2 (FIG. 25A) are replaced with current sources P1 and P2 (FIG. 25B) to carry out a simulation as shown in FIGS. 25A and 25B.

In the methods of analyzing a power noise, only an impedance in a metal layer provided on a substrate is considered as an impedance connected to a power supply and a ground in each circuit element, and the noise waveforms of a source voltage and a ground voltage which fluctuate in almost equal amplitudes to each other are obtained as shown in FIGS. 26A and 26B.

In the electric potential fluctuation waveforms of the power supply and the ground which are actually measured by an actual measuring technique developed by the inventors, however, it has been found that the noise on the ground side is smaller than that on the power supply side as shown in FIGS. 27A and 27B (see Kenji Shimazaki, et al, “Dynamic Power-Supply and Well Noise Measurement and Analysis for High Frequency Body-Biased Circuits”, VLSI Circuits Digest of Technical Papers, pp. 84-87, June 2004).

In addition to an enhancement in the degree of an integration, however, the influence of the slight deviation of a logical simulation on a delay cannot be disregarded, and the logical simulation with high precision is required in respect of the analysis of an operation. Referring to a situation in which a noise is analyzed more greatly in a simulation than an actual measurement which is obtained in the actual measurement, particularly, the amount of the delay is to be estimated pessimistically in the design of a large scale integrated circuit. As a result, a chip area is increased and a consumed power is increased. In consideration of such problems, the inventors deeply examined and investigated the factor of an error between the result of a simulation and an actual measured value. As a result, the inventors found that the actual measured value is smaller than the impedances of a power supply and a ground which are considered in the simulation and the factor of the influence depends on the impedance of a substrate which has not been conventionally considered because of a higher resistance density than that of a metal layer by several digits. The substrate really has a high resistance density but is much thicker and wider than the metal layer. For this reason, particularly, the resistance of the metal layer is relatively increased in a microfabricated integrated circuit and cannot be disregarded in respect of a fluctuation in the electric potential of the power supply.

### SUMMARY OF THE INVENTION

The invention has been made in consideration of the actual circumstances and has an object to provide a semiconductor integrated circuit having an excellent operating characteristic with high precision in consideration of a fluctuation in a voltage with higher precision in a microfabrication.

In order to achieve the object, the invention provides a method of analyzing a power noise of a semiconductor integrated circuit device comprising analyzing the power noise in consideration of an influence of an impedance of a substrate.

By this structure, the impedance of the substrate which has not been conventionally considered is taken into consideration. Consequently, precision in the analysis can be enhanced more greatly, a design margin for a power noise in the design of a large scale integrated circuit can be decreased, the degree of the integration of the large scale integrated circuit can be improved and a consumed power can be reduced.

In the method of analyzing a power noise according to the invention, moreover, the power noise is analyzed based on circuit information of the semiconductor integrated circuit device and substrate information about a semiconductor substrate constituting the semiconductor integrated circuit device.

It is assumed that the substrate includes the state of a substrate to influence an impedance such as a structure provided under a metal layer, that is, a well contact, a source and a drain (a diffusion layer), a well, a P-type substrate (an N-type substrate) or a trench.

Accordingly, the power noise is analyzed based on the impedance of the substrate connected to a power wiring, a ground wiring, a substrate wiring or a well control wiring.

In the method of analyzing a power noise according to the invention, furthermore, the substrate information is impedance information of the substrate, and the power noise is analyzed based on the impedance of the substrate connected to a ground wiring.

By this structure, in case of a P-type substrate, generally, the ground wiring is connected in the substrate to form a parallel connecting unit having the impedance of the substrate. Accordingly, the impedance of the substrate can be reduced considerably so that the power noise can be analyzed with higher precision in consideration of the impedance of the substrate.

In the method of analyzing a power noise according to the invention, moreover, the substrate information is impedance information about the substrate, and the power noise is analyzed based on the impedance of the substrate connected to a power wiring.

By this structure, the power noise can be analyzed with higher precision in consideration of the impedance of the substrate connected to the power wiring. In case of a P-type substrate which is generally used widely, the electric potential of the substrate is fixed to a ground and all power wirings are not connected in the substrate. Therefore, the degree of a reduction in the impedance of the substrate is smaller than the impedance of the substrate connected to the ground wiring. In case of the P-type substrate, however, the analysis of the power noise with high precision is implemented in consideration of the impedance of the substrate connected to the ground wiring. On the other hand, in the case in which an N-type substrate is used differently from the foregoing, all of the power wirings are connected in the substrate. Therefore, the influence of the impedance of the substrate connected to the power wiring is increased. In consideration of the increase, it is possible to analyze the power noise with higher precision.

Furthermore, the method of analyzing a power noise according to the invention comprises extracting contact information in a region connected to a wiring such as a power wiring, a ground wiring, a substrate wiring or a well control wiring from the substrate information, wherein the power noise is analyzed based on the extracted contact information.

According to this structure, diffusion layer regions (a contact, a source region and a drain region) to be portions in which the power wiring, the ground wiring, the substrate wiring and the well control wiring are connected to the substrate are extracted to analyze the power noise. Therefore, the substrate is connected to the diffusion layer to be the contact region. Consequently, it is possible to efficiently analyze the power noise of the substrate.

Moreover, the method of analyzing a power noise according to the invention comprises extracting contact information in a region connected to a power wiring from the substrate information, wherein the power noise is analyzed based on the extracted contact information.

According to this structure, the contact information in the region connected to the power wiring is extracted to analyze the power noise. Therefore, the substrate is connected to the contact. Consequently, it is possible to efficiently analyze the power noise of the substrate.

Furthermore, the method of analyzing a power noise according to the invention comprises dividing the substrate into meshes to carry out modeling, wherein the substrate information is mesh information.

According to this structure, the division into meshes is carried out three-dimensionally and a model such as an equivalent circuit in the estimation of the power noise is obtained as the substrate information in regions thus divided and is treated as the mesh information. Consequently, it is possible to carry out the analysis with high precision while simplifying data.

In the method of analyzing a power noise according to the invention, moreover, the modeling includes carrying out a division into meshes on the basis of a contact position to perform modeling.

According to this structure, the division into meshes is carried out on the basis of the contact position so that the power supply is connected. On the basis of the contact position, therefore, it is possible to easily carry out a connection later. In particular, it is possible to easily carry out a connection on the basis of contact coordinates from information about the coordinates of the power supply and the ground wiring which is described in a net list including the power supply and the ground wiring on a transistor level output by using an existing LPE tool.

In the method of analyzing a power noise according to the invention, furthermore, the modeling includes carrying out a division into meshes on the basis of a diffusing position to perform modeling.

According to this structure, the division into meshes is carried out on the basis of the diffusing position including the source and drain regions. Consequently, it is possible to easily investigate the influence on the power noise by the junction capacitance of the source and drain regions and the substrate on the basis of the diffusing position.

In the method of analyzing a power noise according to the invention, moreover, the modeling includes carrying out a division into meshes on the basis of a cell position to perform modeling.

According to this structure, the division into meshes is carried out on the basis of the cell position. Consequently, it is possible to easily perform an analysis on a unit of the same cell as an LPE tool or a power noise analyzing tool on a gate level.

In the method of analyzing a power noise according to the invention, furthermore, the modeling includes carrying out a division into uniform meshes to perform modeling, and executing bonding to coordinates of the closest power LPE net list to contact coordinates of the substrate in the uniform meshes thus modeled.

According to this structure, any of the modeled uniform meshes which is the closest to the contact coordinates is bonded to the coordinates of the power LPE net list. Therefore, it is possible to easily carry out the modeling.

In the method of analyzing a power noise according to the invention, moreover, the modeling includes carrying out a division into uniform meshes to perform modeling, and executing bonding to coordinates of the closest power LPE net list to diffusion coordinates of the substrate in the uniform meshes thus modeled.

According to this structure, any of the modeled uniform meshes which is the closest to the contact coordinates is bonded to the coordinates of the power LPE net list. Therefore, it is possible to easily model an equivalent circuit which is necessary for the analysis of the power noise.

In the method of analyzing a power noise according to the invention, furthermore, the modeling includes carrying out modeling by a division in a vertical direction of the substrate, and the substrate information is information being identified in the vertical direction of the substrate.

According to this structure, a current is reduced gradually in the direction of a depth so that the influence of a fluctuation in a voltage is lessened. By using the information identified in the direction of the depth, therefore, an analysis with high precision can be carried out more easily with a small data volume.

In the method of analyzing a power noise according to the invention, moreover, the modeling includes carrying out modeling by a division every cell, a point is placed on one spot in a cell to be noted from the modeled information, and an impedance corresponding to a distance from the point being considered as substrate information.

According to this structure, the impedance corresponding to the distance from the point is considered as the substrate information. Therefore, the analysis with high precision can be carried out more easily.

In the method of analyzing a power noise according to the invention, furthermore, the modeling includes carrying out modeling by a division every cell, and a substrate contact or a diffusion is previously aggregated on a unit of a cell to create aggregation information from the modeled information.

According to this structure, the modeling is carried out by a division every cell and the aggregation is then performed on a unit of the cell. Therefore, a data volume can be reduced, and furthermore, a matching property with a gate level analysis can be enhanced.

In the method of analyzing a power noise according to the invention, moreover, the modeling includes extracting a well or a diffusion region to come in contact with a ground wiring from the substrate information, and substituting a region corresponding to the well or the diffusion region which is extracted for wiring information corresponding to a different layer.

According to this structure, the power wiring and the ground wiring are treated as separate layers. Consequently, it is possible to individually give the resistance densities of the power wiring and the ground wiring. Thus, it is possible to carry out an analysis with a change in the resistance densities of the power supply and the ground in consideration of the influence of the substrate by exactly using a current EDA tool environment.

Furthermore, the method of analyzing a power noise according to the invention comprises changing a resistance value of the ground wiring in consideration of an influence of the substrate.

According to this structure, the resistance value of the ground wiring is calculated in advance and a substitution for the same value is carried out. Consequently, a substitution with high precision can be performed more easily.

In the method of analyzing a power noise according to the invention, moreover, the resistance value of the ground wiring is multiplied by a desirable coefficient in consideration of the influence of the substrate.

According to this structure, a constant by which the resistance value of the ground wiring is to be multiplied is calculated in advance and the same value is multiplied. Consequently, a substitution with high precision can be carried out more easily.

Furthermore, the invention provides an apparatus for analyzing a power noise comprising an extractor which extracts wiring information and substrate information from circuit information, and an analyzer which analyzes the power noise based on the wiring information and the substrate information.

Moreover, the method of analyzing a power noise according to the invention comprises analyzing a substrate noise of the semiconductor integrated circuit device.

According to this structure, it is possible to analyze the substrate noise together with the power noise. Consequently, it is possible to analyze an influence such as a delay, a skew or a malfunction in a transistor at time of the simultaneous generation of the power supply and the substrate.

Furthermore, the method of analyzing a power noise according to the invention comprises adding information about a peripheral circuit on an outside of the semiconductor integrated circuit device to information about a circuit in the semiconductor integrated circuit device.

According to this structure, it is possible to analyze a situation in which the power noise on the semiconductor integrated circuit device is influenced by the impedance of a package or a printed circuit board. In addition, it is also possible to analyze the power noise or the substrate noise which makes a round between terminals depending on a connecting relationship among wirings over the printed circuit board.

In addition, the method of analyzing a power noise according to the invention comprises adding impedance information of a package and a printed circuit board, or the package or the printed circuit board as the information about the peripheral circuit on the outside of the semiconductor integrated circuit device.

According to this structure, it is possible to analyze the power noise and the substrate noise in consideration of an influence on the outside of a semiconductor device while preventing an increase in a time required for the analysis through an active element on the printed circuit board.

Furthermore, the invention provides an optimizing method comprising optimizing a layout of the semiconductor integrated circuit device based on a result of an analysis which is obtained by using the method of analyzing a power noise of a semiconductor integrated circuit device.

As described above, according to the invention, the impedance of the substrate is considered in the analysis of the power noise of the semiconductor integrated circuit. Therefore, it is possible to take a countermeasure with higher precision before the manufacture of the semiconductor integrated circuit, to decrease a design margin for the power noise and to enhance a noise resistance.

### BRIEF DESCRIPTION OF THE DRAWINGS

FIG. 1 is a diagram showing a semiconductor integrated circuit according to a first embodiment of the invention;

FIG. 2 is a diagram showing a semiconductor integrated circuit which is modeled according to the first embodiment of the invention;

FIG. 3 is a diagram showing a simulation model creating procedure according to the first embodiment of the invention;

FIG. 4 is a diagram showing a variant of the first embodiment according to the invention;

FIG. 5 is a diagram showing an analyzing apparatus for executing an analysis according to the first embodiment of the invention;

FIG. 6 is a flowchart showing a simulation operation according to a second embodiment of the invention;

FIG. 7 is a diagram showing a model formed by an analyzing method according to the second embodiment of the invention;

FIG. 8 is a diagram showing a model formed by an analyzing method according to a third embodiment of the invention;

FIG. 9 is a diagram showing a model formed by an analyzing method according to a fourth embodiment of the invention;

FIG. 10 is a diagram showing a model formed by an analyzing method according to a fifth embodiment of the invention;

FIG. 11 is a diagram showing a model formed by an analyzing method according to a sixth embodiment of the invention;

FIG. 12 is a diagram showing a model formed by an analyzing method according to a seventh embodiment of the invention;

FIG. 13 is a diagram showing a model formed by an analyzing method according to an eighth embodiment of the invention;

FIG. 14 is a diagram showing a model formed by an analyzing method according to a ninth embodiment of the invention;

FIG. 15 is a diagram showing a model formed by an analyzing method according to a tenth embodiment of the invention;

FIG. 16 is a diagram showing a model formed by an analyzing method according to an eleventh embodiment of the invention;

FIG. 17 is a flowchart showing the analyzing method according to the eleventh embodiment of the invention;

FIG. 18 is a diagram showing a model formed by an analyzing method according to a twelfth embodiment of the invention;

FIG. 19 is a flowchart showing the analyzing method according to the twelfth embodiment of the invention;

FIG. 20 is a flowchart showing an analyzing method according to a thirteenth embodiment of the invention;

FIG. 21 is a diagram showing the analyzing method according to the thirteenth embodiment of the invention;

FIG. 22 is a diagram showing a model formed by an analyzing method according to a fourteenth embodiment of the invention;

FIG. 23 is a diagram showing the model formed by the analyzing method according to the fourteenth embodiment of the invention;

FIG. 24 is a diagram showing a model formed by an analyzing method according to a fifteenth embodiment of the invention;

FIG. 25 is a diagram showing an analyzing method according to a related example;

FIG. 26 is a chart showing electric potential fluctuation waveforms according to the analyzing method of the related example;

FIG. 27 is a chart showing electric potential fluctuation waveforms according to the analyzing method of the related example; and

FIG. 28 is a diagram showing a model formed by an analyzing method according to a sixteenth embodiment of the invention.

### DETAILED DESCRIPTION OF THE PREFERRED EMBODIMENTS

A method of analyzing a power noise according to the invention will be described below in detail with reference to the drawings.

(First Embodiment)

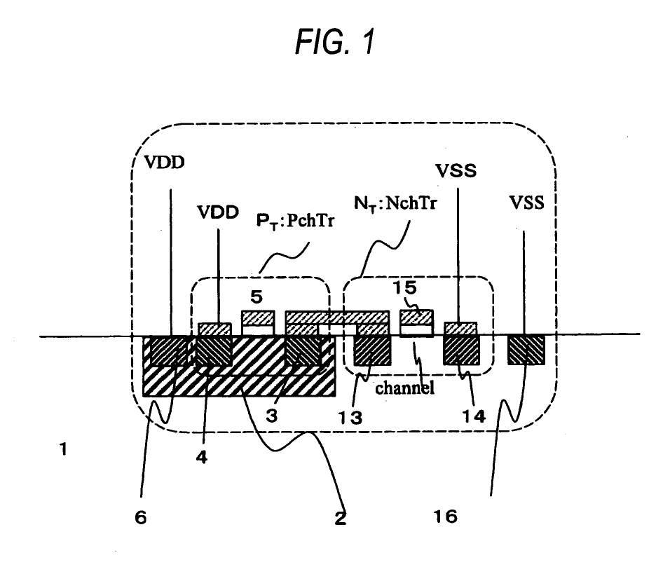

FIGS. 1 to 3 are principle diagrams showing a procedure for analyzing a power noise according to the embodiment.

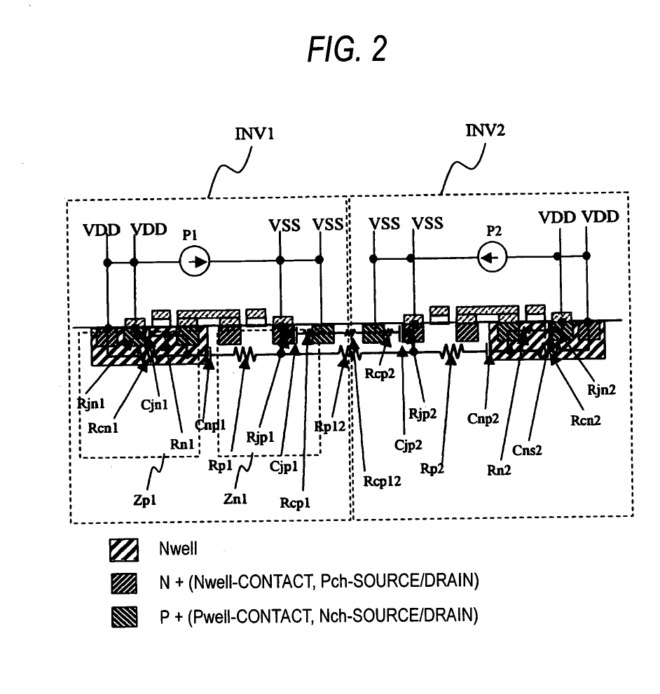

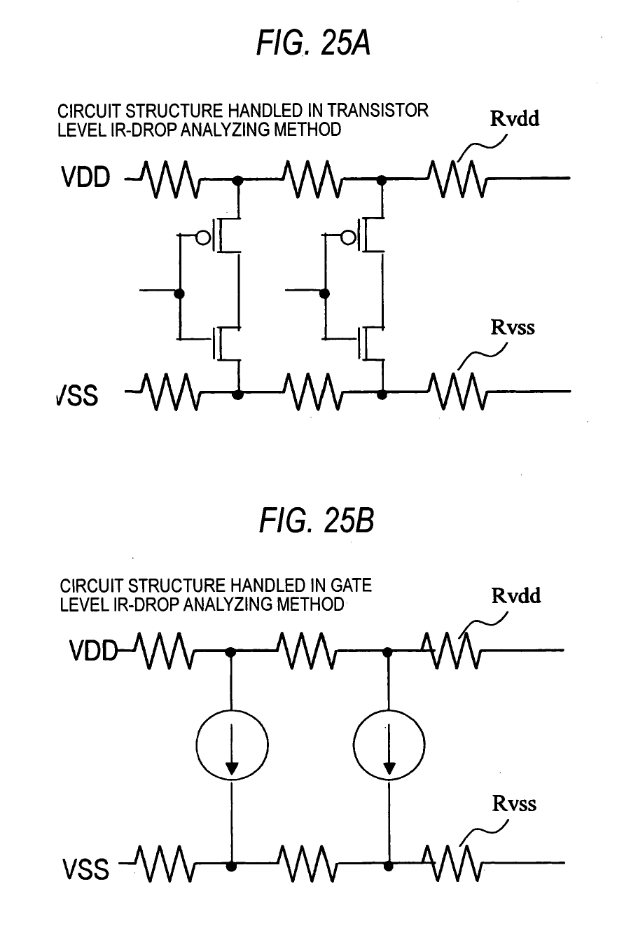

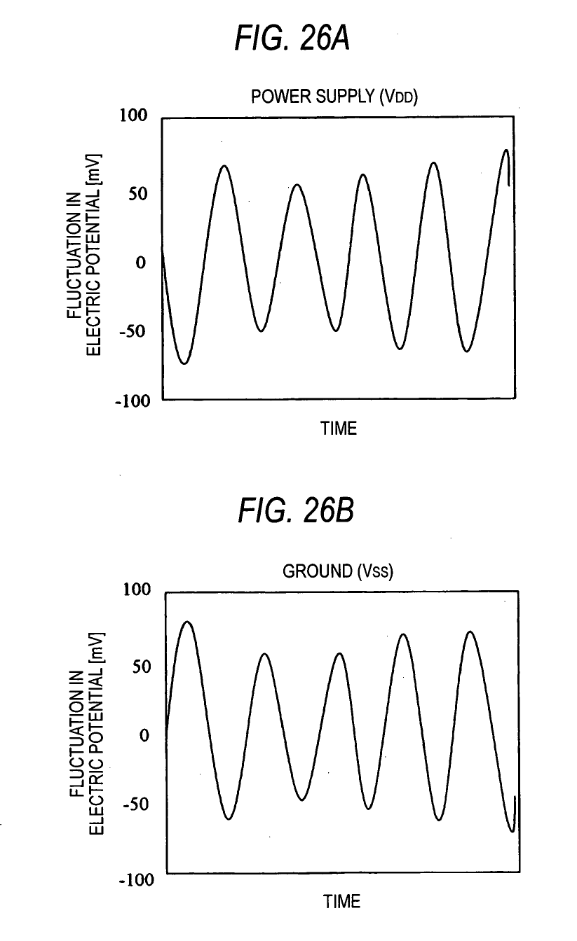

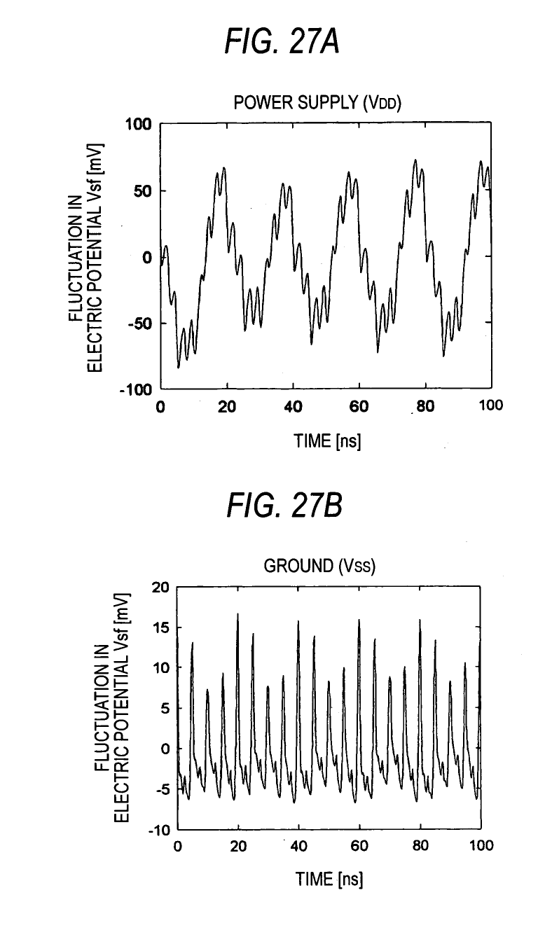

A method of analyzing a power noise of a semiconductor integrated circuit according to the embodiment of the invention is characterized in that a transistor is replaced with a current source Ps as in a related analyzing method (see FIG. 25), and furthermore, a semiconductor integrated circuit including a transistor shown in FIG. 1 is analyzed by using a model considering the impedance of a substrate (structures provided under a metal layer, for example, a P-type substrate or an N-type substrate, a well and a diffusion region are generally referred to as the substrate) as shown in FIG. 2. More specifically, the method is characterized in that modeling is carried out as a combination of an N-type diffusion resistance Rⱼₙ, a P-type diffusion resistance Rⱼₚ, a junction capacitance Cⱼₙ of an N-type diffusion region, a junction capacitance Cⱼₚ of a P-type diffusion region, a P-type substrate resistance Rₚ, an N well resistance Rₙ, an N-P capacitance Cₙₚ of an N well—P-type silicon substrate and a contact resistance R_{c} in a substrate as shown in FIG. 2 in a structure in which a P-channel transistor P_{T} and an N-channel transistor N_{T} are formed in a silicon substrate 1 as shown in FIG. 1. In this example, a twin well structure is used. In case of a triple well structure, a P well in the N well is present. For this reason, the junction capacitance of the N well and the P well is applied in addition to the power noise analyzing model.

In the semiconductor integrated circuit, a gate electrode 5 and source and drain regions 4 and 3 are formed in an N well 2 provided on the surface of a silicon substrate 1 so that a P channel transistor is formed, and furthermore, source and drain regions 14 and 13 are provided in the silicon substrate 1 so that an N-channel transistor is formed. A power wiring V_{DD} is connected to an N-type contact 6 and the P-type source region 4 of the P-channel transistor in the N well 2, and furthermore, a ground wiring V_{SS} is connected to the N-type source region of the N-channel transistor and a P-type contact 16 of the substrate.

FIG. 2 shows an example in which a circuit is modeled for analyzing a power noise in the case in which a plurality of transistors is provided in the integrated circuit. In this example, for simplicity of the description, two inverters INV1 and INV2 are present. As shown in FIG. 2, modeling is carried out in such a configuration that the inverters INV1 and INV2 constituted by the P-channel transistor P_{T} and the N-channel transistor N_{T} in FIG. 1 are set to be current sources P₁ and P₂ between power supplies V_{DD} and V_{SS} respectively, and furthermore, the impedance of the substrate is added. An impedance Zₙ₁ is obtained by modeling the substrate impedance of the N-channel transistor N_{T} in FIG. 1. Modeling is carried out with a diffusion resistance Rⱼₚ₁ in the N-type diffusion region 14 of the source, a junction capacitance Cⱼₚ₁ of the N-type diffusion region 14 of the source and the substrate, a resistance Rₚ₁ of the P-type silicon substrate, and a resistance R_{cp1} of the P-type contact (including the resistance of the P-type silicon substrate), and a value thus obtained is considered as an impedance to be connected in parallel with the ground wiring V_{SS} in the contact and the diffusion region.

Moreover, the impedance Zₙ₁ is obtained by modeling the substrate impedance of the P-channel transistor P_{T} in FIG. 1 for the analysis of a power noise. The modeling is carried out with the diffusion resistance Rⱼₚ₁ in the P-type diffusion region 4 of the source, a junction capacitance Cⱼₙ₁ in the diffusion region of the P-type diffusion region 4 of the source, a resistance Rₙ₁ of the N well, and a resistance (including the resistance of the N well) R_{cn1} of the N-type contact, and a value thus obtained is considered as an impedance to be connected in parallel with the power wiring V_{DD}.

Impedances Zₚ₁ and Zₙ₁ are connected through a capacitance Cₙₚ₁ between the P-type silicon substrate 1 and the N well 2 and are thus modeled.

Moreover, the inverters INV1 and INV2 are connected through a resistance Rₚ₁₂ of the P-type silicon substrate and a P-type contact resistance (including the resistance of the P-type silicon substrate) R_{cp12} and are thus modeled.

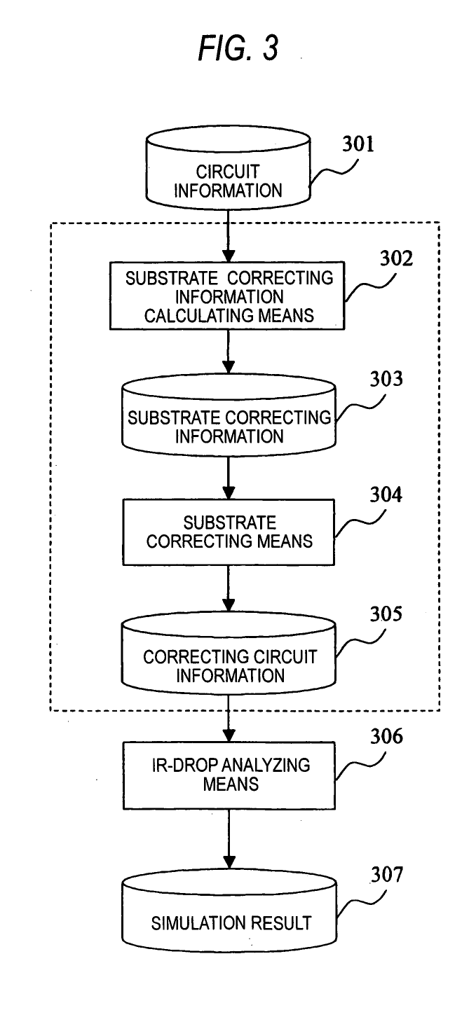

When a simulation is to be carried out based on circuit information 301 by power noise analyzing means (IR-DROP analyzing means) 306 and a simulation result 307 is to be output as shown in a flowchart of FIG. 3, a correction is carried out in consideration of the state of the substrate. More specifically, substrate correcting information 303 is output from the circuit information 301 by substrate correcting information calculating means 302 in consideration of the impedance of a substrate (a well, a diffusion region and a P substrate), correcting circuit information 305 is obtained by substrate correcting means 304 based on the substrate correcting information 303, and a simulation is carried out by the power noise analyzing means (IR-DROP analyzing means) 306 based on the correcting circuit information 305 so that the simulation result 307 is output.

A portion surrounded by a broken line in the drawing indicates a feature portion in the embodiment. The circuit information implies layout information or net list information.

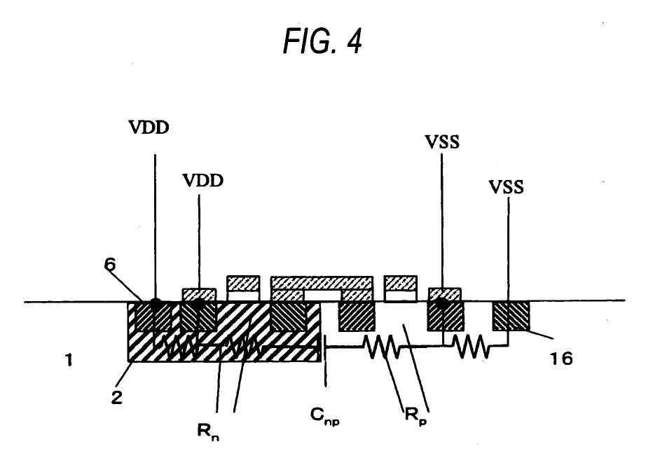

In place of FIG. 2, moreover, diffusion regions in the substrate, that is, a contact and a source and drain may be connected through an equivalent RC net and the inside of the substrate may be replaced with a simplified equivalent circuit model as shown in FIG. 4. A PN junction portion becomes a capacitance and can be represented by Cₙₚ. The result of the connection is shown as a model in FIG. 2. As is apparent from the drawing, a large number of power wirings V_{DD} are connected to the capacitance and the amount of a reduction in an impedance is smaller than that in the ground wiring V_{SS} but the impedance is reduced. On the other hand, a large number of ground wirings are connected in parallel with the resistors and a voltage drop is great in many cases.

Accordingly, a reduction in the impedance by the substrate is calculated for only the ground wiring (only the power wiring in case of the N-type silicon substrate) and for both the ground wiring and the power wiring, and these information can also be stored in a library and be used as library information. By applying this operation to a cell, it is possible to form a cell library in the same manner.

Based on the circuit information, then, reference is made to the library and a delay value corresponding to the circuit information in the library is fetched (a delay calculating step), and a power noise is analyzed based on the same value to estimate a timing and to analyze a timing error, thereby taking out a timing report and changing a layout in order to optimize the timing. For a method of improving the layout, it is also effective to reduce the impedance of the substrate by regulating the structure, material and impurity concentration of the substrate including the well and the diffusion region in addition to the optimization of a delay time as in the related art.

By this method, a fluctuation in a voltage is calculated in consideration of the impedance of the substrate. Therefore, it is possible to carry out the analysis with high precision.

By this structure, moreover, an impedance to be used for calculating a fluctuation in a voltage is fetched from the library. Therefore, it is possible to prevent a deterioration in a characteristic and to reduce a data volume.

An apparatus for analyzing a power noise based on a fluctuation in a voltage to be used herein comprises a computer system including a substrate consideration calculating portion 101 for carrying out a processing of each step for each component related to a calculation to take a substrate into consideration, a power noise calculating portion 106 for carrying out a processing of each step for each component related to the calculation of a power noise, an input/output calculating portion 107 for carrying out a processing of each step for each component related to the calculation of a user interface, an input device 103 such as a keyboard, an external storage device 104 such as a memory device or a disk device, and an output device 105 such as a display. It is also possible to use the substrate consideration calculating portion 101, the calculating portion 106 and the input/output calculating portion 107 singly, in mutual cooperation with each other or in combination with the contents of the calculating portion other than those described in the invention.

In the power noise calculating portion 106, a calculation is carried out in relation to a target network and the amount of a fluctuation in a voltage is calculated. The substrate consideration calculating portion 101 creates correcting information for adding substrate information to the target network or power noise information thus analyzed in order to take the substrate information into consideration for the power noise information calculated by the power noise calculating portion 106. The input/output calculating portion 107 carries out a correction over the input information (the circuit information) or the output information (the power noise information) calculated by the power noise calculating portion 106 based on the correcting information calculated by the substrate consideration calculating portion 101.

A layout is regulated corresponding to the fluctuation in the voltage thus obtained, thereby carrying out an optimization. Thus, a design is optimized. The substrate impedance of the ground wiring is smaller than that of the power wiring. For this reason, the impedance of the ground wiring is smaller than that of the power wiring. By changing a design to preferentially set the drawing distance of the power wiring to be smaller than that of the ground wiring, therefore, it is possible to carry out the optimization. By the regulation of the structure, material and impurity concentration of the substrate including the well and the diffusion region, moreover, the substrate impedance is reduced.

According to the method, the diffusion layer regions (the contact, the source region and the drain region) to be portions in which the power wiring, the ground wiring, the substrate wiring and the well control wiring are connected to the substrate are extracted to analyze the power noise. Consequently, the substrate is connected to the diffusion layer to be the contact region. Thus, it is possible to efficiently analyze the power noise of the substrate with higher precision.

(Second Embodiment)

Next, description will be given to an example in which the inside of a substrate is divided into meshes and modeling is carried out by an equivalent circuit according to a second embodiment of the invention.

While the description has been given to the example in which the diffusion regions are connected through the equivalent RC net in the first embodiment, description will be given to an example in which the substrate is divided into three-dimensional meshes to carry out the modeling in the embodiment.

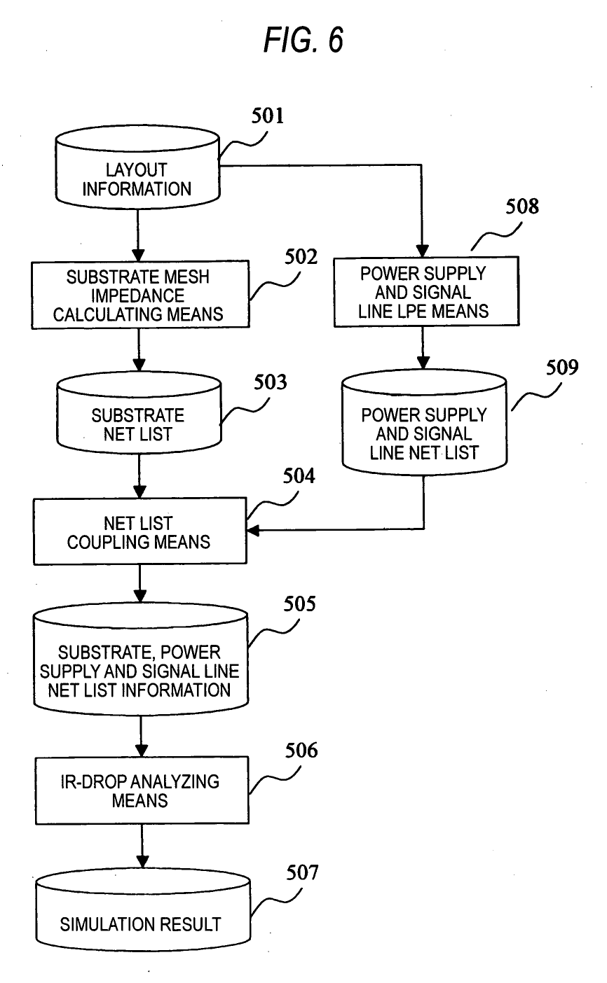

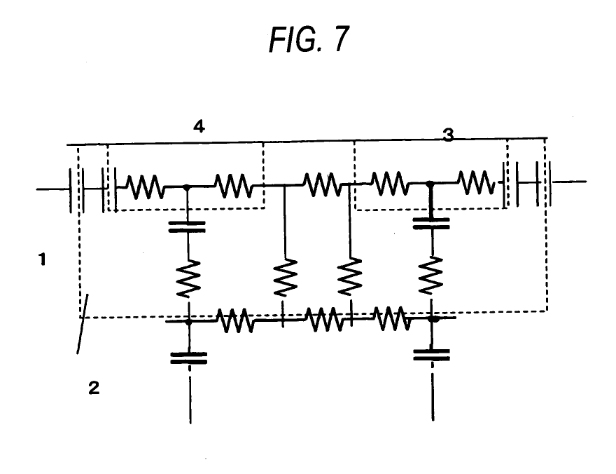

FIG. 6 is a flowchart showing the embodiment, and FIG. 7 is a diagram in which the impedance of the substrate 1 (see FIG. 1) used in the first embodiment is divided into meshes and is thus modeled.

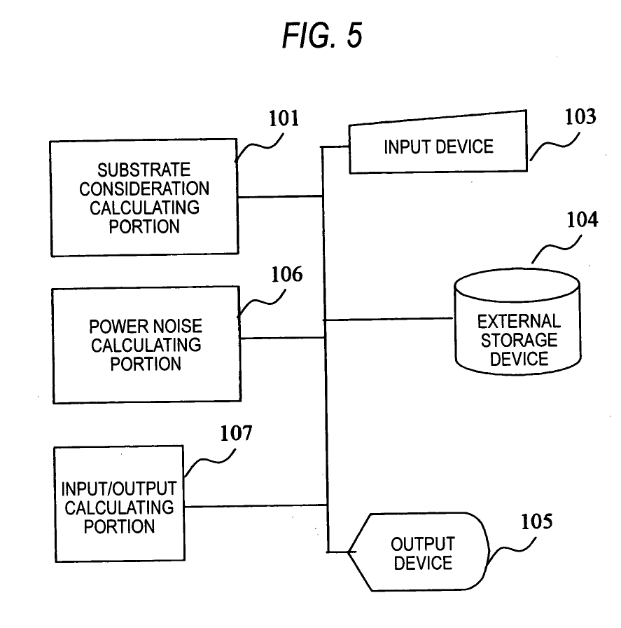

Layout information 501 is used for circuit information as shown in FIG. 5 and an impedance is calculated for each mesh by substrate mesh impedance calculating means 502, thereby forming a substrate net list 503. A broken line in an N well 2 indicates a source region 4 and a drain region 3 respectively, and it is possible to obtain model information obtained by carrying out the division into the meshes to perform the modeling.

On the other hand, a power supply and signal line net list 509 is formed by using power supply and signal line LPE means 508 based on the layout information 501.

Then, the substrate net list 503 (see FIG. 7) obtained from the substrate mesh impedance calculating means 502 and the power supply and signal line net list 509 obtained from the power supply and signal line LPE means 508 are coupled to each other through net list coupling means 504 so that substrate, power supply and signal line net list information 505 is obtained.

Thus, a simulation is carried out by power noise means (IR-DROP analyzing means) 506 based on the substrate, the power supply and signal line net list information 505 to which the substrate information is added so that a simulation result 507 is output.

While a set of R and C is made between the meshes to form an RC model in the embodiment, it is also possible to take an inductance into consideration. Consequently, the modeling can be carried out with higher precision. Although the RCs between the meshes are connected in series, moreover, they may be connected in parallel depending on a structure. Moreover, it is also possible to use the form of an impedance, that is, an S matrix.

According to the method, it is possible to carry out an analysis with high precision while simplifying data.

(Third Embodiment)

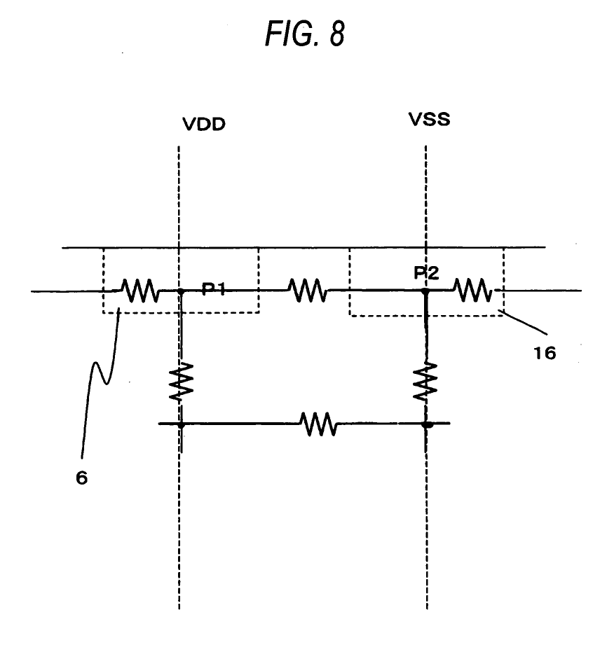

In a third embodiment according to the invention, next, description will be given to a method of analyzing a power noise in which a division into meshes is carried out on the basis of a contact position, thereby performing modeling. In this example, the division into meshes is carried out on the basis of the contact position, thereby performing the modeling in place of modeling between points as shown in an explanatory diagram of FIG. 8.

A division into meshes passing through a contact 6 (a point P1) to an N well 2 and a contact 16 (a point P2) to a P substrate is carried out to perform the modeling.

For example, a contact is formed in the position of a diffusion region on the basis of the position of the diffusion region in many cases. Therefore, it is possible to easily carry out an analysis on the basis of the contact position.

When the contact is thus set to be the basis, moreover, existing means such as an LPE tool can easily be used in a subsequent connection.

When a depth is increased in a vertical direction, the amount of a current is decreased. Even if an impedance is equal, therefore, a fluctuation in a voltage is lessened. If a certain coefficient is multiplied in the vertical direction, consequently, it is possible to carry out a detection with higher precision.

(Fourth Embodiment)

In a fourth embodiment according to the invention, next, description will be given to an example in which a division into meshes is carried out on the basis of the positions of source and drain diffusion regions 13 and 14 in a transistor and modeling is thus performed.

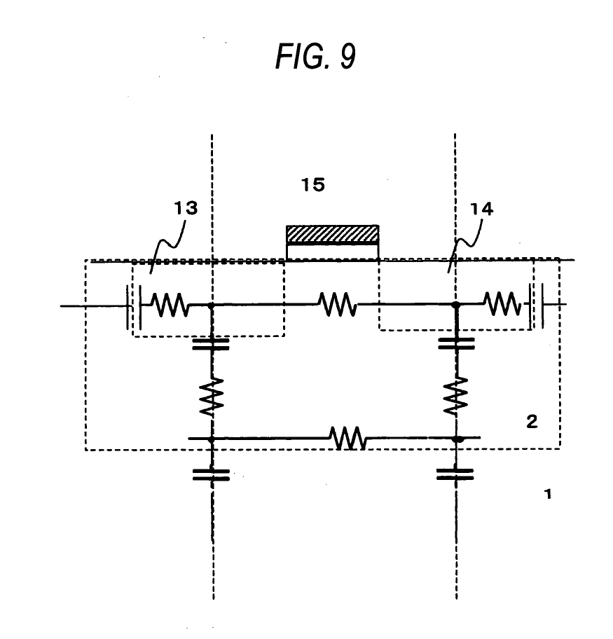

In this example, as shown in an explanatory diagram of FIG. 9, a division into meshes is carried out on the basis of the positions of the source and drain regions and the modeling is thus performed, and a replacement with an RC equivalent circuit is executed. There is shown only a P channel transistor Tᵣₚ side formed in an N well 2.

In the embodiment, thought a data volume is increased more than that in the third embodiment, a calculation with higher precision can be carried out.

(Fifth Embodiment)

In a fifth embodiment according to the invention, next, description will be given to an example in which a division into meshes is carried out on the basis of a well and modeling is thus performed.

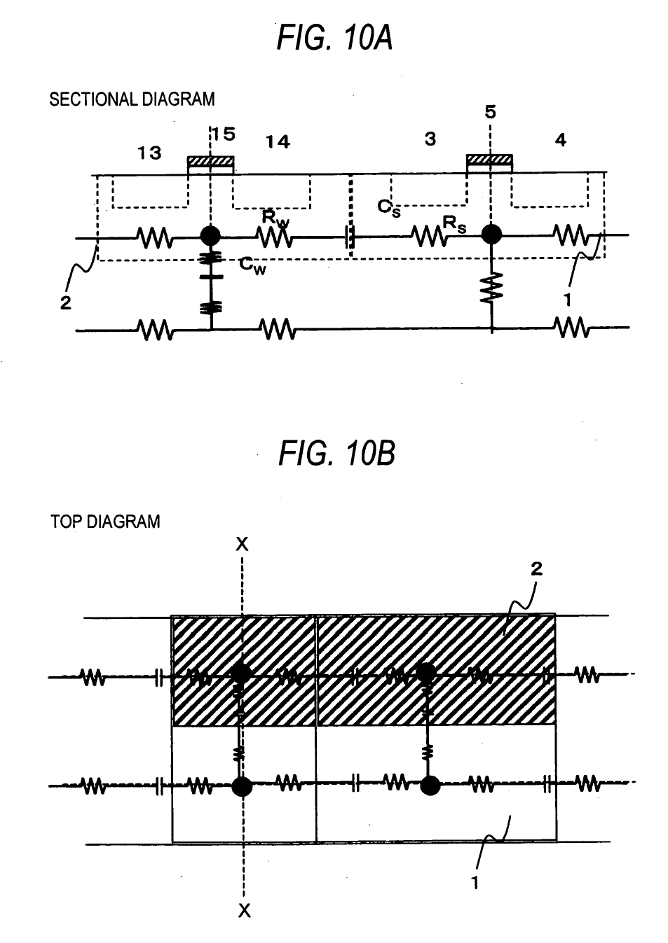

In this example, as shown in explanatory diagrams of FIGS. 10A and 10B, a well is divided into a resistor and a capacitance and is thus modeled, and an N well 2 is represented by a well resistor R_{w} and a junction capacitance C_{w} between the well and a substrate, and a P-type silicon substrate 1 is represented by a substrate resistor Rₛ and a substrate capacitance Cₛ (an N well—substrate capacitance Cₙₚ). In an ordinary standard cell, a P well is generated in a P-type silicon substrate. In the drawing, for simplicity of the description, the P well is simply referred to as a P-type silicon substrate (P-substrate) together.

FIG. 10A is a sectional diagram taken along X-X in FIG. 10B. Also in this example, similarly, modeling is carried out over the structure in which a P-channel transistor P_{T} and an N-channel transistor N_{T} are formed in the silicon substrate 1 in FIG. 1. Also in this example, in the same manner as in the first embodiment, a gate electrode 5 and source and drain regions 4 and 3 are formed in an N well 2 provided on the surface of the silicon substrate 1 so that the P-channel transistor P_{T} is formed, and furthermore, the N-channel transistor N_{T} is formed in such a manner that a drain region 13 comes in contact with the source region 4 of the P-channel transistor P_{T}. A power wiring V_{DD} is connected to the N well 2 and a source region 14 of the N-channel transistor N_{T}, and furthermore, a ground wiring V_{SS} is connected to the drain region of the P-channel transistor P_{T} and a P-type contact 16 of the substrate. Moreover, the junction capacitance C_{w} is formed between the P-type silicon substrate 1 and the N well 2, and furthermore, a large number of substrate resistors are formed in the P-type silicon substrate 1.

According to the method in accordance with the embodiment, a small data volume is sufficient. Therefore, it is possible to reduce the amount of a calculation.

(Sixth Embodiment)

In a sixth embodiment according to the invention, next, description will be given to an example in which a division into meshes is carried out on the basis of a cell position and modeling is thus performed.

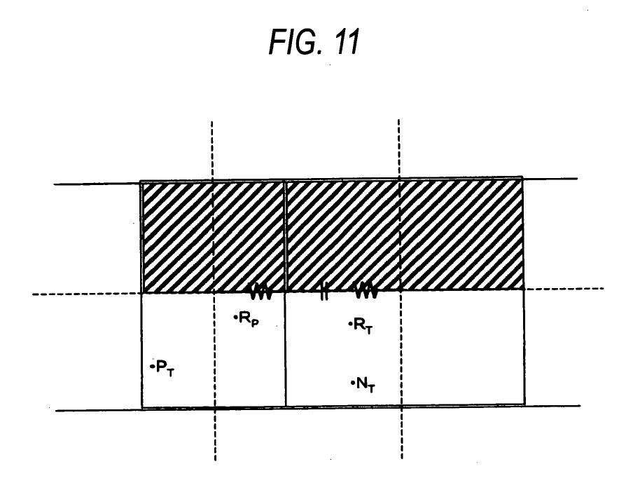

In this example, as shown in an explanatory diagram of FIG. 11, each transistor cell is grasped as RC and a V_{DD} side is not considered but only a V_{SS} side is considered.

Herein, a P-channel transistor P_{T} and an N-channel transistor N_{T} are modeled as resistors R_{P} and R_{N}, respectively.

Only a ground side is particularly influenced greatly by a substrate. Consequently, it is possible to carry out a calculation with higher precision without increasing the amount of the calculation.

By using the method together with the fifth embodiment to carry out a division through a well, it is also possible to model a power supply V_{DD} and a ground V_{SS}.

In this example, a point is provided on one spot in a cell and is set to be a measuring point. By adding an impedance, it is possible to easily carry out the modeling. Thus, there is a feature that coordinates can easily be matched.

(Seventh Embodiment)

In a seventh embodiment according to the invention, next, description will be given to an example in which a division into uniform meshes is carried out and each of the meshes is bonded to the coordinates of the closest power LPE net list to contact coordinates to perform modeling.

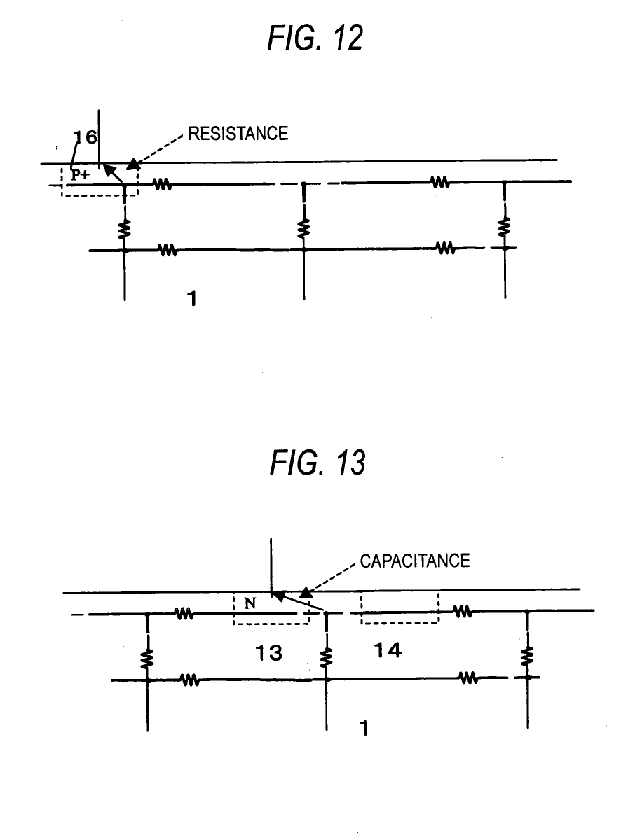

In this example, as shown in an explanatory diagram of FIG. 12, each of the meshes is grasped as RC which is bonded to the coordinates of the closest power LPE net list and they are treated integrally.

Herein, there is a feature that the P-type silicon substrate 1 having the P-channel transistor P_{T} and the N-channel transistor N_{T} formed therein as shown in FIG. 1 is divided into meshes having uniform sizes which are bonded through the P⁺ contact 16 (see FIG. 1) formed in the P-type silicon substrate 1.

Consequently, it is possible to easily perform the modeling and to carry out a calculation with higher precision without increasing the amount of the calculation.

(Eighth Embodiment)

In an eighth embodiment according to the invention, next, description will be given to an example in which a division into uniform meshes is carried out and each of the meshes is bonded to the coordinates of the closest power LPE net list to diffusion coordinates to perform modeling.

In this example, as shown in an explanatory diagram of FIG. 13, each of the meshes is bonded to the coordinates of the closest power LPE net list to the positions of the diffusion coordinates of a source region 14 and a drain region 13, and they are treated integrally.

Consequently, it is possible to easily model a necessary equivalent circuit for the analysis of a power noise and to carry out a calculation with higher precision without increasing the amount of the calculation.

(Ninth Embodiment)

In a ninth embodiment according to the invention, next, description will be given to an example in which a division into uniform meshes is not carried out but modeling is performed in such a manner that the meshes are gradually coarser with an increase in a depth in a vertical direction.

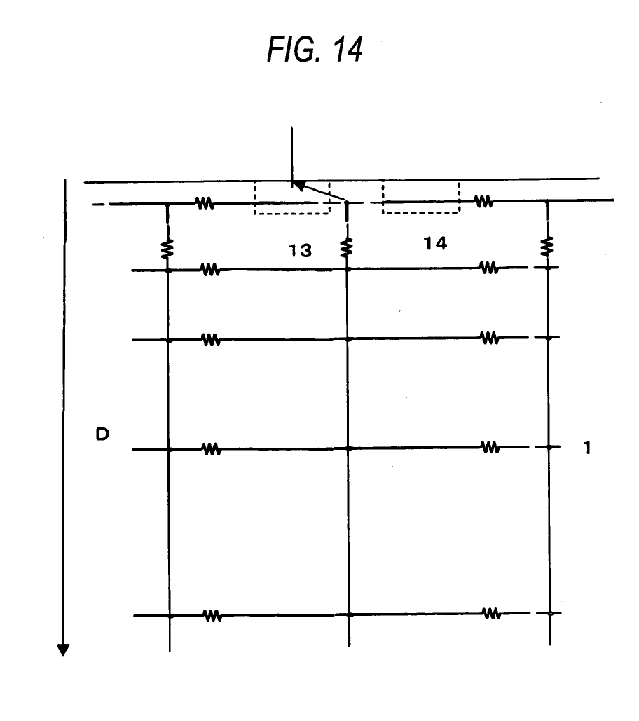

In this example, as shown in an explanatory diagram of FIG. 14, each of the meshes is divided to be coarser with an increase in a depth in a vertical direction D and the modeling is thus carried out.

Also in this example, each of the meshes is bonded to the coordinates of the closest power LPE net list to the positions of the diffusion coordinates of a source region 14 and a drain region 13 and they are treated integrally in the same manner as in the eighth embodiment.

When the depth is increased in the vertical direction of the substrate, the amount of a current is reduced so that an influence is lessened. Even if the mesh is caused to be coarse in the vertical direction D of the substrate, therefore, precision can be prevented from being reduced.

Consequently, it is possible to reduce a data volume without deteriorating the precision, thereby decreasing the amount of a calculation more greatly.

(Tenth Embodiment)

A tenth embodiment according to the invention is characterized in that a division into uniform meshes is carried out, and each region is then compressed and simplified into RC to perform modeling.

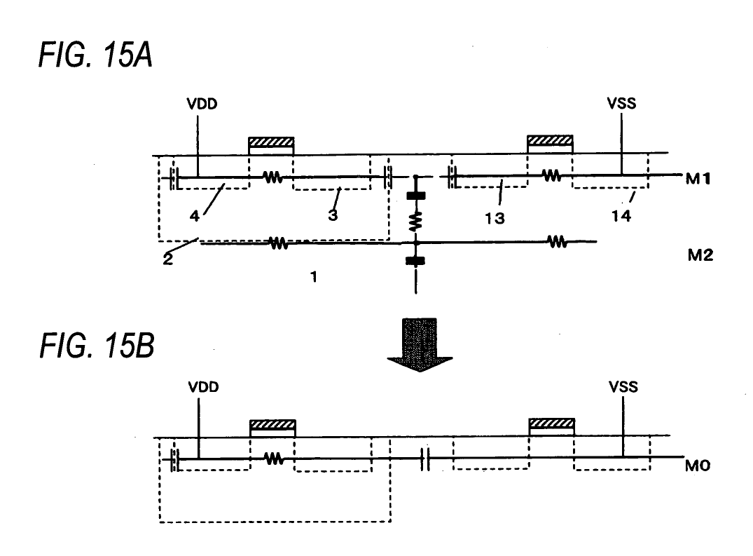

In this example, as shown in an explanatory diagram of FIG. 15, a division into meshes is carried out to perform modeling (FIG. 15A) and any of the data on the mesh in a deep position are partially removed (FIG. 15B) and are compressed.

In this example, a P-type silicon substrate 1 having a P-channel transistor P_{T} and an N-channel transistor N_{T} formed thereon as shown in FIG. 1 is divided into meshes and is modeled as shown in FIG. 15A. Herein, only two layers M1 and M2 on a surface are shown.

As shown in FIG. 15B, then, only a surface layer is left and lower layers are removed, and the surface layer is modeled as MO.

When a depth is increased in the vertical direction of the substrate, the amount of a current is reduced so that an influence is lessened. Even if the data are removed in the vertical direction of the substrate, therefore, precision can be prevented from being reduced.

Consequently, it is possible to reduce a data volume and to decrease the amount of a calculation more greatly without reducing the precision.

(Eleventh Embodiment)

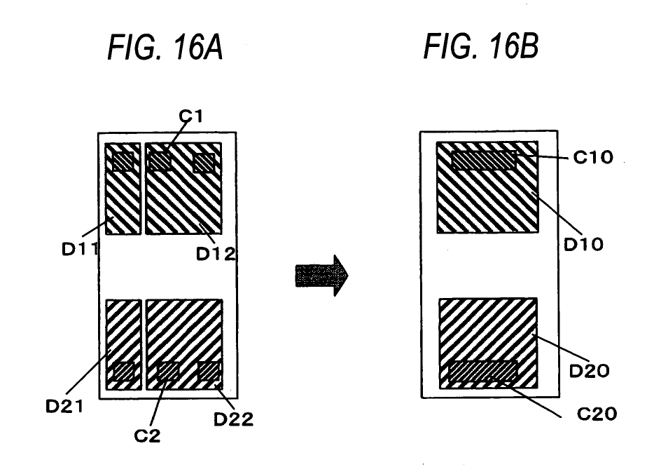

An eleventh embodiment according to the invention is characterized in that substrate contacts c1 and c2 and diffusion regions D11, D12, D21 and D22 are aggregated on a unit of a cell as shown in FIGS. 16A and 16B, and are collected into substrate contacts c10 and c20 and diffusion regions D10 and D20 every cell respectively and are thus modeled.

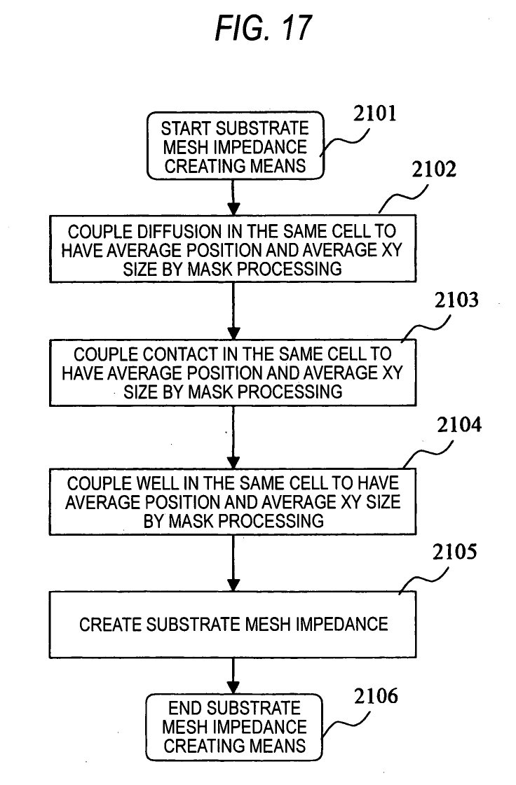

FIG. 17 is a flowchart showing the foregoing.

The driving operation of substrate mesh impedance creating means is started (Step 2101).

Then, diffusions in the same cell are aggregated and are coupled and arranged as a total size in an average position (Step 2102).

Furthermore, contacts in the same cell are coupled as an average XY size in an average position (Step 2103).

Thereafter, wells in the same cell are coupled as an average XY size in an average position (Step 2104).

Subsequently, a substrate mesh impedance is created (Step 2105).

Thus, the creation of the substrate mesh impedance as the aggregated data is completed (Step 2106).

Consequently, the density of a substrate contact is increased very greatly with a microfabrication and a high integration of a semiconductor integrated circuit. Consequently, there is a problem in that an ordinary analysis tool is utilized with difficulty because of an excessively great load and a large amount of use of a memory. By preparing and replacing the cell through a previous aggregation, thus, it is possible to shorten a time required for the processing of the memory. The replacement of the cell can be processed at a very high speed.

Although the replacement of the cell may be carried out over a layout, it is also possible to create internal information over a program.

By previously forming an aggregated cell as a library, moreover, it is possible to simplify the processing without reducing precision. Furthermore, a matching property with a gate level analysis can be enhanced.

(Twelfth Embodiment)

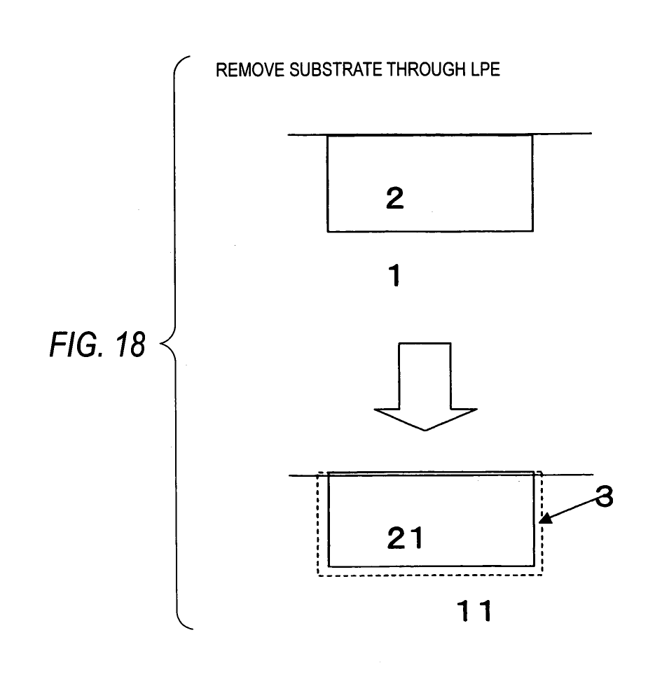

A twelfth embodiment according to the invention is characterized in that modeling is carried out to replace a well 2 formed in a substrate 1 with a metal 21 and to provide a metal 11 to be the substrate and the metal 21 with an insulating film 3 interposed therebetween as shown in FIG. 18.

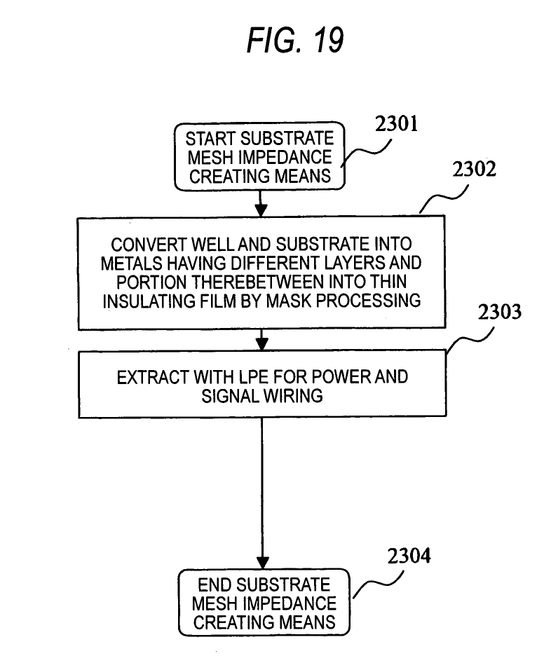

FIG. 19 is a flowchart showing the foregoing.

The driving operation of substrate mesh impedance creating means is started (Step 2301).

Then, a well and a substrate in the same cell are changed into metals having different layers and a layer is converted as a thin insulating film therebetween (Step 2302).

Furthermore, an extraction is carried out by using LEP for a power and signal wiring (Step 2303).

Thereafter, a substrate mesh impedance is created (Step 2304).

Consequently, substrate information is substituted for metal information. Therefore, it is possible to use a wiring analysis tool.

A thick substrate is also substituted for a metal. Differently from an actual condition, therefore, it is possible to obtain high precision in a pattern without increasing the amount of a calculation in consideration of only a surface layer having a predetermined depth.

It is desirable that approximately 30 μm, preferably 80 μm of data should be previously fetched from the surface and should be thus prepared.

(Thirteenth Embodiment)

While the compression of data has been described in the embodiments, this embodiment is characterized in that the resistance values of a ground wiring and a power wiring are changed based on the influence of a substrate.

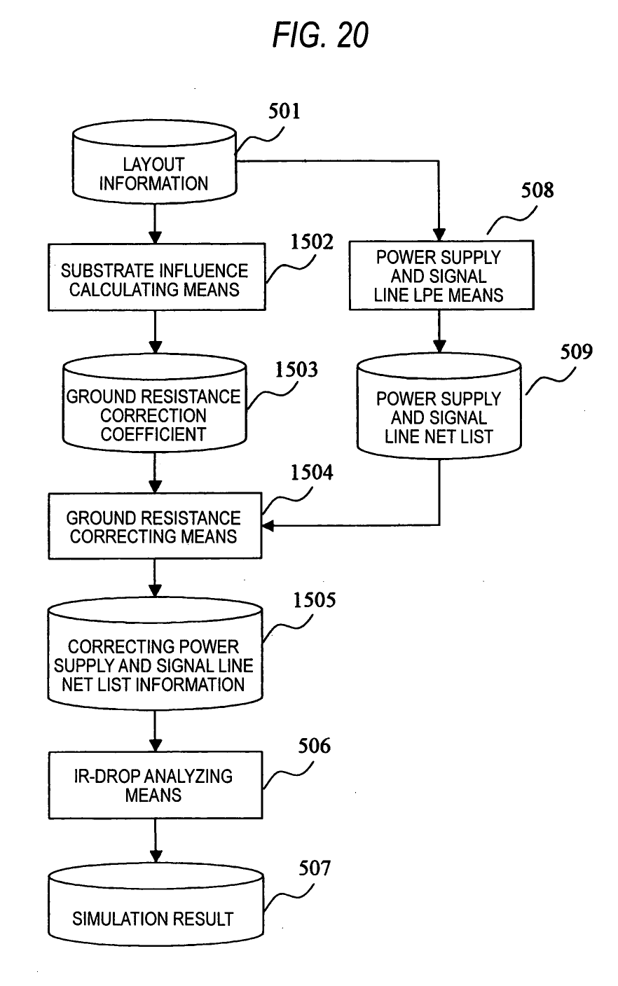

FIG. 20 is a schematic explanatory diagram showing the embodiment.

As shown in FIG. 20, layout information 501 is used as circuit information and the influence of a substrate on the resistance of a power supply or a ground is calculated for the ratio of the area of a contact (or a diffusion region) to the area of a whole integrated circuit in consideration of a contact resistance determined depending on a process to be used by substrate influence calculating means 1502.

On the other hand, a power supply and signal line net list 509 is formed based on the layout information 501 by using power supply and signal line LPE means 508.

Then, coupling is carried out by ground resistance correcting means 1504 based on a ground resistance correction coefficient 1503 obtained from the substrate influence calculating means 1502 and the power supply and signal line net list 509 obtained from the power supply and signal line LPE means 508 so that correcting power supply and signal line net list information 1505 is obtained.

More specifically, the influence of the substrate on the resistance of the power supply or the ground is calculated as the ground resistance correction coefficient 1503 with respect to the ratio of the area of the contact (or the diffusion region) to the area of the whole integrated circuit in consideration of the contact resistance determined depending on the process to be used previously, and the actual resistance of the power supply or the ground obtained from the power supply and signal line net list 509 acquired from the power supply and signal line LPE means 508 is multiplied by the coefficient in the ground resistance correcting means 1504 so that the correcting power supply and signal line net list information 1505 is obtained.

Based on the correcting power supply and signal line net list information 1505 to which substrate information is added, thus, a simulation is carried out by power noise analyzing means (IR-DROP analyzing means) 506 so that a simulation result 507 is output.

It is possible to use the same means for the power supply in addition to the ground. In that case, the means is used for the power supply if the diffusion region is present in an N well, and the same means is used for the ground if the diffusion region is present in a P well. Consequently, it is possible to accurately treat the influence of a substrate impedance on the power supply and that of the substrate impedance on the ground. Thus, it is possible to obtain a result with higher precision.

In the embodiment, the influence of the substrate on the resistance of the power supply or the ground is calculated for the ratio of the area of the contact (or the diffusion region) to the area of the whole integrated circuit in consideration of the contact resistance determined depending on the process to be used. Consequently, modeling can be carried out with higher precision.

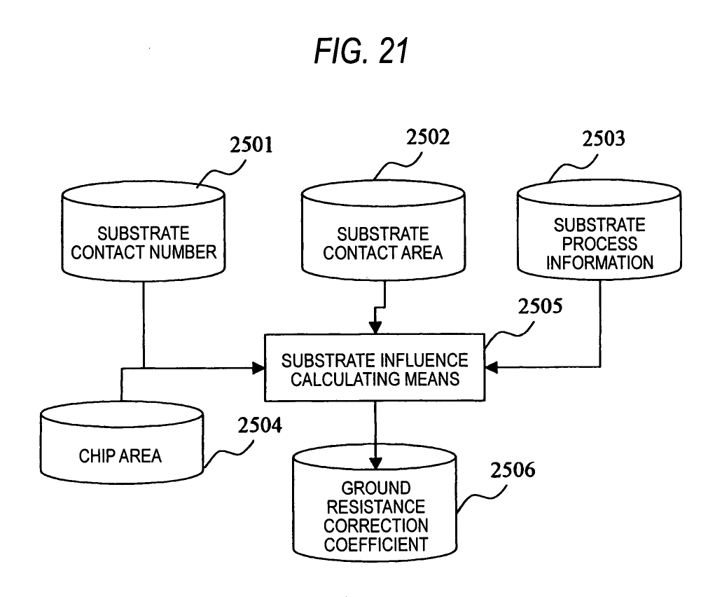

While the resistance value is calculated by the modeling in the embodiment, a ground resistance correction coefficient 2506 may be calculated by substrate influence calculating means 2505 corresponding to a substrate contact number 2501, a substrate contact area 2502, substrate process information 2503 and a chip area 2504 and a resistance value may be multiplied by the ground resistance correction coefficient 2506 as shown in FIG. 21.

(Fourteenth Embodiment)

The embodiment is characterized in that a layout layer is changed based on the attribute of a ground wiring or a power wiring. In the embodiment, the resistance values of the ground and the power wiring are changed based on the influence of a substrate.

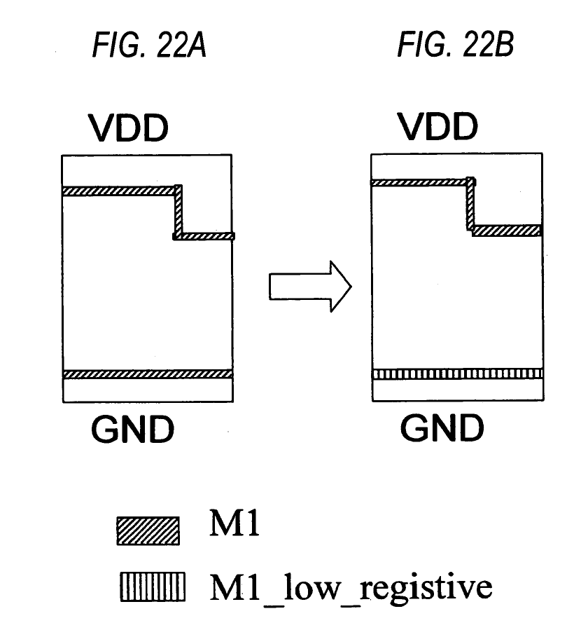

FIG. 22 is a schematic explanatory diagram showing the embodiment.

In the fourteenth embodiment according to the invention, a VDD side is often placed apart through a well and an impedance is slightly reduced, while a ground side is wholly connected and a resistance is reduced because of a parallel connection. For this reason, there is a feature that a layout layer is previously changed in order to distinguish a ground wiring and a power wiring which are created by the same layer M1 as shown in FIG. 22A from each other as shown in FIG. 22B.

By treating the power wiring and the ground wiring as separate layers, it is possible to individually give the resistance densities of the power wiring and the ground wiring. Consequently, it is possible to carry out an analysis in which the resistance densities of the power supply and the ground are changed in consideration of the influence of the substrate by exactly using an existing EDA tool environment.

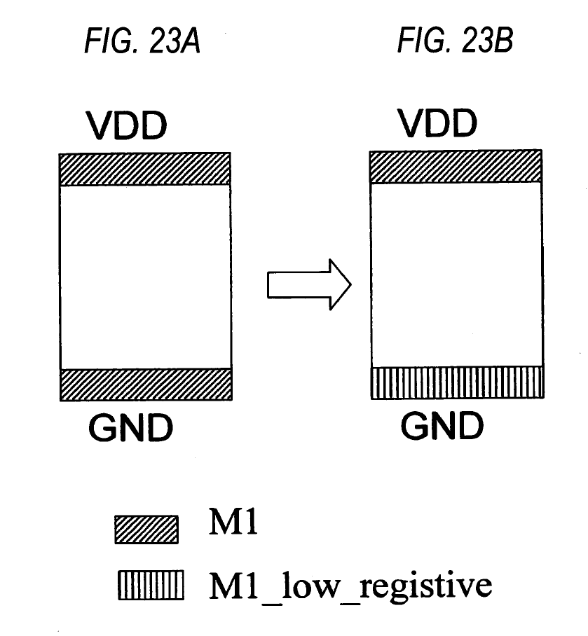

As shown in FIG. 23A, moreover, a ground wiring and a power wiring which are created by the same layer M1 may be substituted for a cell prepared by previously changing a layout layer in order to distinguish the ground wiring and the power wiring from each other as shown in FIG. 23B.

(Fifteenth Embodiment)

In the embodiment, the impedance of a substrate is not formally changed into a network but is grounded in each area.

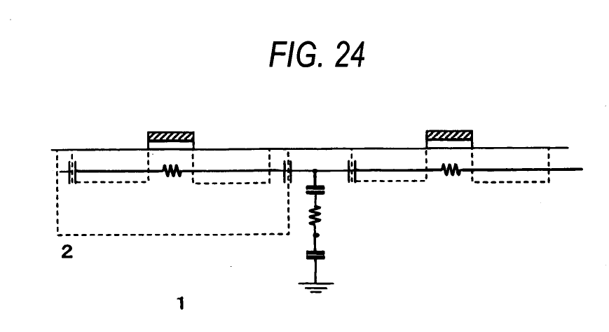

As shown in FIG. 24, the impedance of the substrate in a wiring network is not taken into consideration but is earthed in each area.

Consequently, the amount of use of a memory can be reduced, and furthermore, a simulation speed can be enhanced.

When a voltage is analyzed to carry out grounding in each area, thus, the amount of use of the memory and a time required for a processing are increased. According to this structure, however, the amount of the processing can be reduced and the amount of information can be compressed. Consequently, the amount of use of the memory can be reduced, and furthermore, an operating speed can be enhanced.

In an optimization, a virtual change is carried out and an analysis is then performed again, and a result thereof is reported. Consequently, it is possible to easily obtain the best layout through some processes.

The compressing method is not restricted to the embodiment but a compressing method such as AWE (Asymptotic Waveform Evaluation) can also be used, for example.

(Sixteenth Embodiment)

Next, description will be given to a method of simultaneously analyzing a substrate noise and carrying out the analysis including a peripheral network on the outside of a semiconductor circuit device according to a sixteenth embodiment of the invention.

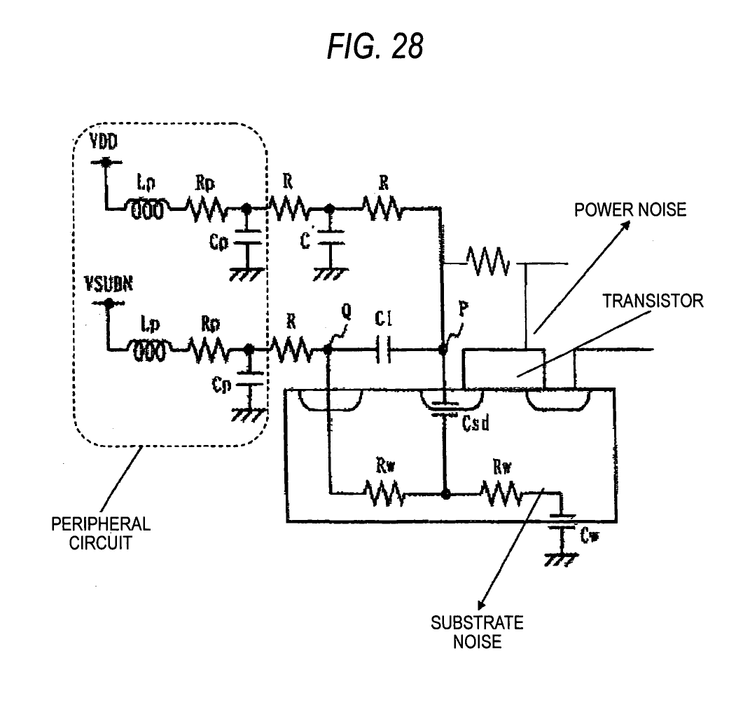

FIG. 28 is a diagram in which the impedance of a peripheral circuit (a package or a printed circuit board) on the outside of the semiconductor circuit device is coupled to the impedance of the substrate 1 (see FIG. 1) used in the first embodiment and they are thus modeled. The modeling of the impedance of the peripheral circuit can be calculated by a technique referred to as SPICE by using the electromagnetic field analyzing tool of the package or the printed circuit board. The SPICE is well-known and description will be omitted. While the equivalent impedance of the package or the printed circuit board is added as the peripheral circuit on the outside of the semiconductor device in the example, another semiconductor device on the outside of the semiconductor device or a peripheral circuit including an active element may be added.

The external impedance of the semiconductor circuit device and the impedance of the network in the semiconductor circuit device are coupled in the same process as the coupling of a power wiring and a substrate wiring in the net list coupling means. The coupling is carried out from an I/O pad in the semiconductor circuit device to the pin of a package through the wire of the package. Therefore, a connection is performed based on connection information about the position of the I/O pad and the pin of the package which are used in a process for wire bonding to be carried out when enclosing the semiconductor circuit device in the package.

In the embodiment, furthermore, the analysis is carried out for a substrate noise (a fluctuation in the noise of the electric potential of the substrate) in addition to a power noise. It is possible to obtain the fluctuation in the noise of the electric potential of the substrate by observing a voltage or current waveform in the process of a power noise analysis at a node between the impedances in a substrate net list.

By observing the noise waveform of the substrate in the same portion as a place for the observation in the analysis of the power noise in directions other than the vertical direction of the substrate or surrounding coordinates, it is possible to simultaneously obtain the influences of the power noise and the substrate noise on the delay, skew and malfunction of a transistor.

As described above, according to the invention, it is possible to implement the analysis of the power noise with higher precision in consideration of the impedance of the substrate. Consequently, it is possible to carry out an application to various semiconductor integrated circuit devices.

What is claimed is:

1. A method of analyzing a power noise of a semiconductor integrated circuit device comprising:
analyzing the power noise in consideration of an influence of an impedance of a substrate constituting the semiconductor integrated circuit device.

2. The method of analyzing a power noise of a semiconductor integrated circuit device according to claim 1, wherein the power noise is analyzed based on circuit information of the semiconductor integrated circuit device and substrate information about a substrate constituting the semiconductor integrated circuit device.

3. The method of analyzing a power noise of a semiconductor integrated circuit device according to claim 2,
wherein the substrate information is impedance information of the substrate; and
wherein the power noise is analyzed based on the impedance of the substrate connected to a ground wiring.

4. The method of analyzing a power noise of a semiconductor integrated circuit device according to claim 2,
wherein the substrate information is impedance information about the substrate; and
wherein the power noise is analyzed based on the impedance of the substrate connected to a power wiring.

5. The method of analyzing a power noise of a semiconductor integrated circuit device according to claim 2, further comprising:
extracting diffusion layer information in a region connected to a ground wiring from the substrate information,
wherein the power noise is analyzed based on the extracted diffusion layer information.

6. The method of analyzing a power noise of a semiconductor integrated circuit device according to claim 2, further comprising:
extracting diffusion layer information in a region connected to a power wiring from the substrate information,
wherein the power noise is analyzed based on the extracted diffusion layer information.

7. The method of analyzing a power noise of a semiconductor integrated circuit device according to claim 1, further comprising:
dividing the substrate into meshes to carry out modeling,
wherein the substrate information is mesh information.

8. The method of analyzing a power noise of a semiconductor integrated circuit device according to claim 7, wherein the modeling includes carrying out a division into meshes on the basis of a contact position to perform modeling.

9. The method of analyzing a power noise of a semiconductor integrated circuit device according to claim 7, wherein the modeling includes carrying out a division into meshes on the basis of a diffusing position to perform modeling.

10. The method of analyzing a power noise of a semiconductor integrated circuit device according to claim 7, wherein the modeling includes carrying out a division into meshes on the basis of a cell position to perform modeling.

11. The method of analyzing a power noise of a semiconductor integrated circuit device according to claim 7,
wherein the modeling includes:
carrying out a division into uniform meshes to perform modeling; and
executing bonding to coordinates of the closest power LPE net list to contact coordinates of the substrate in the uniform meshes thus modeled.

12. The method of analyzing a power noise of a semiconductor integrated circuit device according to claim 7,
wherein the modeling includes:
carrying out a division into uniform meshes to perform modeling; and
executing bonding to coordinates of the closest power LPE net list to diffusion coordinates of the substrate in the uniform meshes thus modeled.

13. The method of analyzing a power noise of a semiconductor integrated circuit device according to claim 7,
wherein the modeling includes carrying out modeling by a division in a vertical direction of the substrate; and
wherein the substrate information is information being identified in a vertical direction of the substrate.

14. The method of analyzing a power noise of a semiconductor integrated circuit device according to claim 7,
wherein the modeling includes carrying out modeling by a division every cell; and
wherein a point is placed on one spot in a cell to be noted from the modeled information, and an impedance corresponding to a distance from the point is considered as substrate information.

15. The method of analyzing a power noise of a semiconductor integrated circuit device according to claim 7,
wherein the modeling includes carrying out modeling by a division every cell; and
wherein a substrate contact or a diffusion is previously aggregated on a unit of a cell to create aggregation information from the modeled information.

16. The method of analyzing a power noise of a semiconductor integrated circuit device according to claim 7,
wherein the modeling includes:
extracting a well or a diffusion region to come in contact with a power wiring, a ground wiring, a substrate wiring or a well control wiring from the substrate information; and
substituting a region corresponding to the well or the diffusion region which is extracted for wiring information corresponding to a different layer.

17. The method of analyzing a power noise of a semiconductor integrated circuit device according to claim 3, further comprising:
changing a resistance value of the power wiring, the ground wiring, the substrate wiring or the well control wiring in consideration of an influence of the substrate.

18. The method of analyzing a power noise of a semiconductor integrated circuit device according to claim 17, wherein the resistance value of the power wiring, the ground wiring, the substrate wiring or the well control wiring is multiplied by a desirable coefficient in consideration of the influence of the substrate.

19. The method of analyzing a power noise of a semiconductor integrated circuit device according to claim 1, further comprising:
substituting a ground wiring and a power wiring for different cells.

20. The method of analyzing a power noise of a semiconductor integrated circuit device according to claim 1, further comprising:
analyzing a substrate noise of the semiconductor integrated circuit device.

21. The method of analyzing a power noise of a semiconductor integrated circuit device according to claim 1, further comprising:
adding information about a peripheral circuit on an outside of the semiconductor integrated circuit device to information about a circuit in the semiconductor integrated circuit device.

22. The method of analyzing a power noise of a semiconductor integrated circuit device according to claim 21, further comprising:
adding impedance information of a package and a printed circuit board, or the package or the printed circuit board as the information about the peripheral circuit on the outside of the semiconductor integrated circuit device.

23. An apparatus for analyzing a power noise of a semiconductor integrated circuit device for implementing the method of analyzing a power noise of a semiconductor integrated circuit device according to claim 1, comprising:
an extractor which extracts wiring information and substrate information from circuit information; and
an analyzer which analyzes the power noise based on the wiring information and the substrate information.

24. An optimization designing method comprising:
optimizing a layout of the semiconductor integrated circuit device based on a result of an analysis which is obtained by using the method of analyzing a power noise of a semiconductor integrated circuit device according to claim 1.
